(19) United States
(12) Patent Application Publication
(10) Pub. No.: US 2021/0316330 A1
(43) Pub. Date: Oct. 14, 2021

(54) DEPOSITION DEVICE

(71) Applicant: Fuchita Nanotechnology Ltd., Chiba (JP)

(72) Inventor: Eiji FUCHITA, Chiba (JP)

(21) Appl. No.: 17/060,695

(22) Filed: Oct. 1, 2020

(30) Foreign Application Priority Data
Apr. 13, 2020 (JP) 2020-071717

(51) Int. Cl. B05D 1/12; C23C 24/04; B05D 1/32; C23C 14/04

(52) U.S. Cl. CPC B05D 1/12; C23C 14/042; B05D 1/32; C23C 24/04

(57) ABSTRACT

A deposition device includes: a generation chamber; a deposition chamber; a transfer tubing; a target; a stage; and a mask member. The target is disposed in the deposition chamber, has an irradiation surface to be irradiated with the aerosol injected from the nozzle, and causes the raw material particles to be charged to plasma by collision with the irradiation surface. The stage has a support surface that supports a base material, fine particles of the raw material particles produced by discharging of the charged raw material particles being deposited on the base material. The mask member is disposed in the deposition chamber, and inhibits raw material particles specularly reflected on the irradiation surface, of the raw material particles that have been collided with the irradiation surface, from reaching the stage.

### CROSS-REFERENCE TO RELATED APPLICATION

This application claims the benefit of Japanese Priority Patent Application No. 2020-071717, filed Apr. 13, 2020, the entire contents of which are incorporated herein by reference.

### BACKGROUND

The present invention relates to a deposition device using an aerosol deposition method. Aerosol gas deposition (AGD) in which submicron-sized particles such as ceramics are injected from a nozzle at room temperature and deposited on a facing base material is known.

This deposition method is being researched and developed in the environmental and energy fields, the heat-resistant material field, the electronic and device-related fields, and the like as a normal-temperature deposition method for ceramics that is capable of depositing thin insulating films having excellent electrically insulating properties at high speed.

The AGD deposition method is a method in which a raw material powder is gas-transferred and injected from a nozzle to be deposited on a substrate (see, for example, Japanese Patent Application Laid-open No. 2014-9368). At this time, when the raw material powder is directly injected into the substrate, large particles or powders are mixed or taken in the formed film in some cases. There is a high probability that a gap is formed around the large particles taken in the film. As a result, the leakage current increases and the insulating property is inhibited.

In this regard, as a method of inhibiting large particles from mixing into the formed film, for example, a deposition method described in Japanese Patent Application Laid-open No. 2016-27185 has been proposed. In this deposition method, gas is introduced into a hermetically-sealed container housing raw material particles having electrically insulating properties to generate aerosol of the raw material particles, the aerosol is transferred to a deposition chamber whose pressure is lower than that in the hermetically-sealed container through a transfer tubing connected to the hermetically-sealed container, the aerosol is injected from a nozzle attached to the distal end of the transfer tubing toward a target placed in the deposition chamber, the raw material particles are positively charged by being collided with the target, fine particles of the raw material particles are generated by discharging the charged raw material particles, and the generated fine particles are deposited on a base material placed in the deposition chamber.

### SUMMARY

In the technology described in Japanese Patent Application Laid-open No. 2016-27185, the fine particles generated by discharging the charged raw material particles mainly contribute to deposition. However, there are also a large number of particles that do not contribute to deposition in the raw material particles collided with the target, and these fine particles are mixed into the film to reduce the film quality in some cases. In particular, such problems can occur more remarkably in the case of deposition on a wide-area substrate having a large deposition region.

In view of the circumstances as described above, it is an object of the present invention to provide a deposition device capable of inhibiting raw material particles that do not contribute to deposition from mixing into a film.

A deposition device according to an embodiment of the present invention includes: a generation chamber; a deposition chamber; a transfer tubing; a target; a stage; and a mask member.

The generation chamber is configured to be capable of generating aerosol of raw material particles.

The deposition chamber is configured to be maintained at a pressure lower than that of the generation chamber.

The transfer tubing connects between the generation chamber and the deposition chamber, and includes, at a distal end thereof, a nozzle that injects the aerosol.

The target is disposed in the deposition chamber, has an irradiation surface to be irradiated with the aerosol injected from the nozzle, and causes the raw material particles to be charged to plasma by collision with the irradiation surface.

The stage has a support surface that supports a base material, fine particles of the raw material particles produced by discharging of the charged raw material particles being deposited on the base material.

The mask member is disposed in the deposition chamber, and inhibits raw material particles specularly reflected on the irradiation surface, of the raw material particles that have been collided with the irradiation surface, from reaching the stage.

In accordance with the present invention, it is possible to inhibit raw material particles that do not contribute to deposition from mixing into a film.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a schematic configuration diagram of a deposition device according to an embodiment of the present invention;

FIG. 2 is a schematic diagram describing the operation of the above-mentioned deposition device;

FIG. 3 is a side view showing the positional relationship between a nozzle, a target, a mask member, and a stage in the above-mentioned deposition device;

FIG. 4A is a surface photograph of an alumina film deposited without the above-mentioned mask member;

FIG. 4B is a surface photograph of an alumina film deposited with the above-mentioned mask member;

FIG. 5A is a stereomicroscope image of the alumina film deposited without the above-mentioned mask member;

FIG. 5B is a stereomicroscope image of the alumina film deposited with the above-mentioned mask member;

FIGS. 6A to 6C show I-V characteristics normalized by the film thicknesses of alumina films prepared under various conditions;

FIG. 7A shows an I-V characteristic of an alumina film deposited using nitrogen as a carrier gas;

FIG. 7B shows an I-V characteristic of an alumina film deposited using argon as a carrier gas;

FIG. 8 is a side view showing a configuration example of the above-mentioned mask member; and

FIG. 9 is a side view showing another configuration example of the above-mentioned mask member.

### DETAILED DESCRIPTION OF EMBODIMENTS

Hereinafter, an embodiment of the present invention will be described with reference to the drawings.

### [Deposition Device]

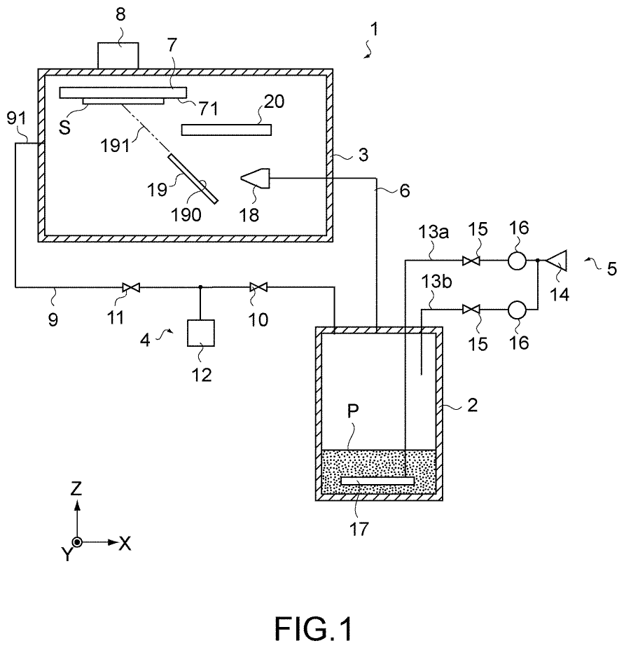

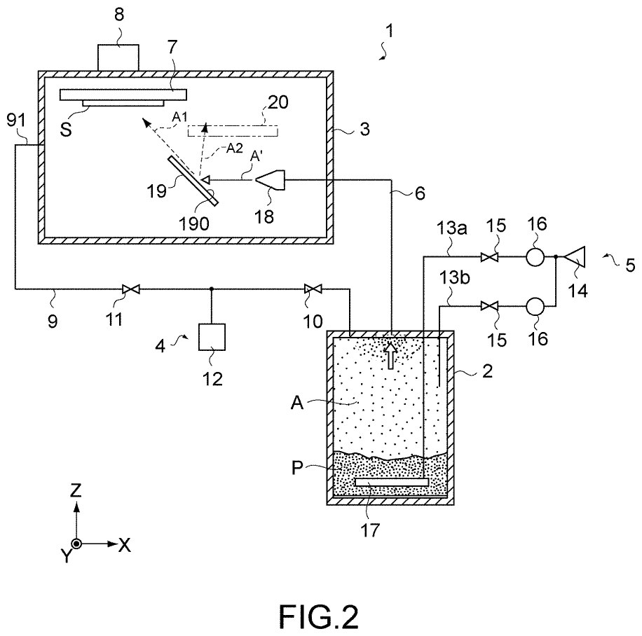

FIG. 1 is a schematic configuration diagram of a deposition device 1 according to an embodiment of the present invention, and FIG. 2 is a schematic diagram describing the operation of the deposition device 1. The deposition device 1 according to this embodiment constitutes an aerosol gas deposition (AGD) device. In the figures, an X-axis, a Y-axis, and a Z-axis direction represent three axial directions perpendicular to each other, and the Z-axis direction represents the vertical direction (the same applies to the following figures).

As shown in FIG. 1, the deposition device 1 includes a generation chamber 2 that generates aerosol of raw material particles P, a deposition chamber 3 that houses a base material S on which deposition is performed, and a transfer tubing 6 that transfers the aerosol from the generation chamber 2 to the deposition chamber 3.

The generation chamber 2 and the deposition chamber 3 are formed independently of each other, and the inner spaces of the chambers communicate with each other through the inside of the transfer tubing 6. The deposition device 1 includes an exhaust system 4 connected to the generation chamber 2 and the deposition chamber 3, and is configured to be capable of exhausting and maintaining the respective chambers in a predetermined reduced-pressure atmosphere. The generation chamber 2 further includes a gas supply system 5 connected to the generation chamber 2, and is configured to be capable of supplying a carrier gas to the generation chamber 2.

The generation chamber 2 houses raw material particles P, which are aerosol raw materials, and aerosol is generated therein. The generation chamber 2 includes, for example, a hermetically-sealed container connected to ground potential, and has a cover (not shown) for moving the raw material particles P in and out. The hermetically-sealed container is formed of metal such as stainless steel, but may be formed of glass. The deposition device 1 may further include a vibrating mechanism that vibrate the generation chamber 2 to stir the raw material particles P or a heating mechanism for degassing (removing water, etc.) the raw material particles P.

The raw material particles P are aerosolized in the generation chamber 2, and deposited on the base material S in the deposition chamber 3. The raw material particles P include fine particles of materials to be deposited. In this embodiment, alumina (aluminum oxide) fine particles are used as the raw material particles P.

Note that in addition thereto, other insulating ceramics fine particles such as zirconium oxide, aluminum nitride, barium titanate can be used as the raw material particles P. Further, the raw material particles P may have a structure in which an electrically insulating film is formed on the surface of a conductor. The particle diameter of the raw material particles P is not particularly limited, and for example, those having a particle diameter of 0.1 μm or more and 10 μm or less are used.

The deposition chamber 3 includes, for example, a hermetically-sealed container formed of stainless steel. A stage 7 having a support surface 71 that supports the base material S is movably disposed inside the deposition chamber 3, and a stage drive mechanism 8 for moving the stage 7 is provided outside the deposition chamber 3. The stage drive mechanism 8 is configured to be capable of reciprocating the stage 7 in the deposition chamber 3 at a predetermined rate in a direction parallel to the deposition surface \of the base material S. In this embodiment, the stage drive mechanism 8 is configured to be capable of moving the stage 7 linearly along the X-axis direction.

The base material S is formed of glass, metal, ceramics, a silicone substrate, or the like. Since the AGD method is capable of performing deposition at room temperature and is a physical deposition method that does not undergo a chemical process, a wide variety of materials can be selected as a base material. Further, the base material S is not limited to a planar one, and may be a steric one.

The deposition chamber 3 and the stage 7 are connected to a ground potential. The stage 7 may include a heating mechanism for degassing the base material S prior to deposition. Further, the deposition chamber 3 may also be provided with a vacuum-gauge to indicate the pressure inside the deposition chamber 3. The deposition chamber 3 is maintained at a pressure lower than that of the generation chamber 2.

The exhaust system 4 evacuates the generation chamber 2 and the deposition chamber 3. The exhaust system 4 includes a vacuum piping 9, a first valve 10, a second valve 11, and a vacuum pump 12. The vacuum pipe 9 includes a branch pipe connecting the vacuum pump 12, the generation chamber 2, and the deposition chamber 3 to each other. The first valve 10 is disposed between the bifurcation of the vacuum pipe 9 and the generation chamber 2, and the second valve 11 is disposed between the bifurcation of the vacuum pipe 9 and the deposition chamber 3. The configuration of the vacuum pump 12 is not particularly limited, and the vacuum pump 12 includes, for example, a multi-stage pump unit including a mechanical booster pump and a rotary pump

The gas supply system 5 supplies a carrier gas for prescribing the pressure of the generation chamber 2 and forming aerosol A (see FIG. 2) to the generation chamber 2. As the carrier gas, for example, N₂, Ar, He, O₂, a mixed gas of N₂ and O₂, dry air, or the like is used. The gas supply system 5 includes gas pipes 13a and 13b, a gas source 14, a third valve 15 disposed to each of the gas pipes 13a and 13b, a gas flow meter 16 disposed to each of the gas pipes 13a and 13b, and a gas ejector 17.

The gas source 14 is, for example, a gas cylinder, and supplies a carrier gas. The gas source 14 is connected to the gas ejector 17 via a gas pipe 13a. The gas pipe 13b is formed by branching off from a gas pipe 13, and the distal end thereof is disposed inside the generation chamber 2. The carrier gas supplied to the generation chamber 2 via the gas pipe 13a is mainly used to wind up the raw material particles P, and the carrier gas supplied to the generation chamber 2 via the gas pipe 13b is mainly used for gas-pressure control of the generation chamber 2.

The gas ejector 17 is disposed inside the generation chamber 2 and uniformly ejects the carrier gas supplied from the gas pipe 13. The gas ejector 17 can be, for example, a hollow body in which a number of gas-ejection holes are provided, and disposed at a position that is covered by the raw material particles P, such as the bottom portion of the generation chamber 2. Thus, the raw material particles P can be efficiently wound up by the carrier gas and aerosolized. The gas flow meter 16 indicates the flow rate of the carrier gas flowing through the gas pipe 13a or 13b. The third valve 15 is configured to be capable of adjusting the flow rate of the carrier gas flowing through the gas pipe 13a or 13b, or shutting off the carrier gas.

The transfer tubing 6 transfers aerosol formed in the generation chamber 2 into the deposition chamber 3 by using the internal pressure difference between the generation chamber 2 and the deposition chamber 3. One end of the transfer tubing 6 is connected to the generation chamber 2. The other end (distal end) of the transfer tubing 6 is located in the deposition chamber 3 and includes a nozzle 18 for injecting aerosol. The transfer tubing 6 and the nozzle 18 are connected to a ground potential.

The nozzle 18 is formed of a metal material such as stainless steel. The passage inner surface of the nozzle 18 through which aerosol passes may be covered by an ultrahard material. As a result, it is possible to suppress wear due to collision with the fine particles constituting aerosol, and improve durability. Examples of the ultrahard material include titanium nitride (TiN), titanium carbide (TiC), tungsten carbide (WC), and diamond-like carbon (DLC).

The inner surface of the transfer tubing 6 is formed of a conductor. Typically, as the transfer tubing 6, a straight metallic tube such as a stainless-steel tube is used. A transfer tubing formed of Teflon (polytetrafluoroethylene) may be used. The length and the inner diameter of the transfer tubing 6 can be appropriately set. For example, the length is 300 mm to 2000 mm and the inner diameter is 4.5 mm to 24 mm.

The opening shape of the nozzle 18 may be a circular shape or a slot-like shape. In this embodiment, the opening shape of the nozzle 18 is a slot-like shape, and the length thereof is 10 times or more and 1,000 times or less as large as the width. In the case where the ratio of the length to the width of the opening is less than 10 times, it is difficult to effectively charge the particles within the nozzle. Further, when the ratio of the length to the width of the opening exceeds 1,000 times, the charging efficiency of the particles is enhanced, but the injecting amount of the fine particles is limited and the deposition rate is remarkably lowered. The ratio of the length to the width of the nozzle opening is favorably 20 times or more and 1,000 times or less, and more favorably 30 times or more and 400 times or less.

The deposition device 1 further includes a target 19 connected to a ground potential. The target 19 is disposed in the deposition chamber 3 and is configured to be capable of charging the raw material particles P by collision with aerosol injected from the nozzle 18. That is, the deposition device 1 according to this embodiment is configured to promote the charging of the raw material particles P by causing aerosol A′ (see FIG. 2) of the raw material particles P injected from the nozzle 18 to collide with the target 19, generate nano-sized fine particles (nanoparticles) by discharging generated by the flying of the charged raw material particles P, and deposit the generated nanoparticles on the base material S.

The charging of the raw material particles P causes light emission of gaseous components in the deposition chamber 3, i.e., plasma, and generates nanoparticles by sputtering the surfaces of the raw material particles P in the plasma. Many of the generated nanoparticles are charged, attracted to and collide with the base material S connected to a ground potential, and deposited on the base material S with electrostatic attraction to the surface of the base material S (see an arrow A1 in FIG. 2). As a result, a dense and highly adherent fine particle film is formed on the base material.

The target 19 is typically formed of a flat plate. However, the present invention is not limited thereto, and the target 19 may be formed of a bulk body such as a block, a column, and a sphere. The target 19 has an irradiation surface 190 to be irradiated with the aerosol A′. The irradiation surface 190 is not limited to a flat surface, and may be a curved surface or a projecting and recessed surface.

As a material forming the target 19, a material that is more likely to be negatively charged than the raw material particles P is typically used. Specifically, in the case where the raw material particles P are alumina particles, a material in which the triboelectric series is located on the negative side than the alumina particles is favorable. Examples of such a material include any one of stainless steel, copper and its alloys, aluminum and its alloys, a conductive material such as graphite, and a semiconductor material such as silicon, or a mixture of two or more of these materials. Further, a laminated body in which such a material is bonded to the surface of the above-mentioned bulk body may be configured as the target 19.

The target 19 is disposed inclined with respect to the nozzle 18 by a predetermined angle such that the aerosol A′ injected from the nozzle 18 is incident at a predetermined incident angle (angle formed by the normal direction of the irradiation surface 190 and the incident direction of aerosol). The above-mentioned incident angle is, for example, 15 degrees or more and 80 degrees or less. As a result, the raw material particles P can be effectively charged. Further, in the case where the raw material particles are alumina particles, the above-mentioned incident angle is, for example, greater than 30 degrees and less than 70 degrees, and more favorably 45 degrees or more and 65 degrees or less. As a result, the charging efficiency of the raw material particles P is enhanced, and the surfaces of the raw material particles P are sputtered in the induced plasma to generate active species which are efficiently miniaturized to a nano-level, whereby an alumina film having an excellent withstand voltage can be formed. The target 19 may be rotatably placed in the deposition chamber 3 so that the above-mentioned incident angle is variable.

The distance between the distal end of the nozzle 18 and the irradiation surface 190 of the target 19 is not particularly limited, and the distance is, for example, 5 mm or more and 50 mm or less. In the case where the above-mentioned distance is less than 5 mm, the effect of the interaction between the positively charged particles in the target 19 and the nozzle 18 (the distal end outer surface is quasi-negatively charged) is increased, and there is a possibility that the charged particles are inhibited from flying to the base material S. Meanwhile, when the above-mentioned distance exceeds 50 mm, the velocity of the raw material powder injected from the nozzle 18 is attenuated, which may reduce efficient collisions with the target 19 and the charging. Further, since the spread of the aerosol A′ injected from the nozzle 18 becomes large, there is a possibility that the target 19 is increased in size. The target 19 may be movably placed in the deposition chamber 3 in the injecting direction of the aerosol A′ such that the above-mentioned distance is variable.

The stage 7 (the base material S) is disposed on an axis 191 that passes through the irradiation surface 190 of the target 19 and is parallel to the irradiation surface 190. That is, the stage 7 is disposed at a position where the aerosol A′ of the raw material particles injected from the nozzle 18 is not on an extension line in the direction of being specularly reflected on the irradiation surface 190 of the target. As a result, raw material particles having relatively large particle diameters, which are pulverized by collision with the irradiation surface 190, the constituent material (see an arrow A2 in FIG. 2) of the target 19 protruding from the irradiation surface 190 by the sputtering action of the raw material particles P injected from the nozzle 18, and the like are suppressed from reaching the base material S. As a result, it is possible to form a dense film including raw material particles having fine particle diameters, in which the raw material particles having large particle diameters and the constituent material of the target 19 are not mixed in the film.

The irradiation surface 190 of the target 19 is disposed inclined at a predetermined angle relative to the normal direction of the surface of the stage 7 (the base material S). In the case where the raw material particles are alumina particles, the above-mentioned predetermined angle is set to, for example, 10 degrees or more and 70 degrees or less, and more favorably 15 degrees or more and 40 degrees or less. The angle of the irradiation surface 190 with respect to the stage 7 (the base material S) may be set to the same angle as the incident angle of aerosol with respect to the target 19, or may be set to an angle different from the incident angle.

The distance between the stage 7 and the target 19 (distances along the Z-axis direction between the point of collision of the aerosol A′ on the irradiation surface 190 and the surface of the stage 7) is not particularly limited, and is, for example, 5 mm or more. In the case where the above-mentioned distance is less than 5 mm, there is a possibility that the target 19 is sputtered by ions in the plasma generated on the surface of the base material S and the constituent material of the target 19 is mixed into the film. The above-mentioned distance is favorably set to 10 mm or more.

The deposition device 1 further includes a mask member 20. The mask member 20 is for inhibiting raw material particles (see the arrow A2 in FIG. 2) specularly reflected on the irradiation surface 190, of the raw material particles collided with the irradiation surface 190 of the target 19, from reaching the base material S on the stage 7. Details of the mask member 20 will be described below.

### [Deposition Method]

Subsequently, referring to FIG. 2, the deposition method according to this embodiment will be described. FIG. 2 is a schematic diagram describing the operation of the deposition device 1.

First, a predetermined amount of the raw material particles P (alumina powder) is housed in the generation chamber 2. The raw material particles P may be subjected to degassing and dehydration treatment by heating in advance. Alternatively, by heating the generation chamber 2, the degassing and dehydration treatment of the raw material particles P may be performed. By degassing and dehydrating the raw material particles P, it is possible to inhibit the raw material particles P from aggregating and accelerate drying to increase the charge content of the raw material particles P.

Next, the generation chamber 2 and the deposition chamber 3 are evacuated to a predetermined reduced-pressure atmosphere by the exhaust system 4. Driving of the vacuum pump 12 is started and the first valve 10 and the second valve 11 are opened. When the generation chamber 2 is sufficiently depressurized, the first valve 10 is closed and the deposition chamber 3 is subsequently evacuated. The generation chamber 2 is evacuated together with the deposition chamber 3 through the inside of the transfer tubing 6. This keeps the deposition chamber 3 at a pressure lower than that of the generation chamber 2.

Next, a carrier gas is introduced into the generation chamber 2 by the gas supply system 5. Each of the third valves 15 of the gas pipes 13a and 13b is opened and the carrier gas is ejected from the gas ejector 17 into the generation chamber 2. The carrier gas introduced into the generation chamber 2 raises the pressure in the generation chamber 2. Further, as shown in FIG. 2, the raw material particles P are wound up by the carrier gas ejected from the gas ejector 17, and aerosol floating in the generation chamber 2, in which the raw material particles P are dispersed in the carrier gas (indicated by A in FIG. 2), is formed. The generated aerosol A flows into the transfer tubing 6 due to the pressure difference between the generation chamber 2 and the deposition chamber 3, and is injected from the nozzle 18. By adjusting the degree of opening of the third valve 15, the pressure difference between the generation chamber 2 and the deposition chamber 3 and the forming condition of the aerosol A are controlled.

The differential pressure between the generation chamber 2 and the deposition chamber 3 is not particularly limited, and is, for example, 10 kPa or more and 180 kPa or less.

Aerosol flowing into the transfer tubing 6 (indicated by A′ in FIG. 2) is ejected at a flow rate defined by the pressure difference between the generation chamber 2 and the deposition chamber 3 and the opening diameter of the nozzle 18. The irradiation surface 190 of the target 19 is irradiated with the aerosol A′ of the raw material particles P injected from the nozzle 18. In addition to the raw material particles P that are positively charged in the generation chamber and fly, the raw material particles P positively charged by collision or friction with the irradiation surface 190 discharge between the raw material particles P and the irradiation surface 190 or surrounding gas molecules to generate carrier gas plasma. The surfaces of the raw material particles P are sputtered by plasma, and thus the raw material particles P are refined. As a result, for example, nano-sized fine particles of 5 nm or more and 25 nm or less are generated. Many of the generated fine particles are charged and are electrostatically attracted to the base material S on the stage 7 connected to a ground potential along the axis indicated by the arrow A1 in FIG. 2 toward the base material S connected to the ground potential. These fine particles may grow or aggregate until reaching the base material S. The fine particles that have reached the surface of the base material S collide with the surface of the base material S and adhere to the surface of the base material S because also an electrostatic attraction force with the base material S is applied. As a result, a fine particle film (alumina film) that is dense and excellent in adhesiveness is formed.

Note that when the fine particles of the charged raw material particles P reach the base material S, discharge phenomena accompanied by light emission occur on the surface of the base material S in some cases. Also in this case, the fine particles are further decomposed by the sputtering action in the plasma, and the particles are deposited on the base material. As a result, the denseness and adhesiveness of the film can be further improved.

Meanwhile, the raw material particles specularly reflected on the irradiation surface 190 of the target 19 and the constituent material of the irradiation surface 190 sputtered by the raw material particles fly along a path indicated by the arrow A2 in FIG. 2. The mask member 20 inhibits the raw material particles specularly reflected on the irradiation surface 190 of the target 19 and the sputtered particles from the target 19 from traveling toward the base material S on the stage 7. As a result, coarse raw material particles and the constituent material of the target 19 are inhibited from being mixed into the coating film on the base material S.

The stage 7 is reciprocated at a predetermined velocity along the in-plane direction of the base material S by the stage drive mechanism 8. As a result, it is possible to form a coating film in a desired region of the surface of the base material S. In this embodiment, since the stage 7 is reciprocated parallel to the X-axis direction, i.e. the flow direction of the gas, an alumina film having an area determined by the moving distances of the stage 7 and the slit width of the nozzle 18 is deposited on the base material S. The film thickness can be adjusted in accordance with the number of scans of the stage 7. Note that since it is likely that the thickness distribution in which the film thickness decreases with distance from the target 19 is obtained, the interference fringes of light caused by the film thickness difference are observed in the deposition outer peripheral region after deposition of a thin film in some cases.

### [Details of Mask Member]

Here, in the deposition device 1 according to this embodiment, the behavior of the raw material particles that contribute to deposition will be described in more detail.

First, raw material particles of ceramics are in contact with a hermetically-sealed container formed of metal in the generation chamber 2, and positively charged by separation of charges when the raw material particles separate from the hermetically-sealed container. The larger the sizes of the raw material particles, the larger the total amount of charge. In addition, contact with the transfer tubing 6 or a narrowed portion of the entrance of the nozzle 18 during the gas-transferring process increase the amount of charge of the raw material particles. It is believed that the charging of raw material particles occurs mainly in the generation chamber 2.

When the charged particles are injected from the nozzle 18 and approach the irradiation surface 190 of the target 19, electrons are ejected from the grounded target 19 toward the charged particles. This ejection of electrons turn the gas in the vicinity thereof into plasma. In order to maintain the plasma, it is essential to fly positive particles and supply electrons. The ground conductive target plate also serves as a source of electrons. The positive ions of the plasma sputter the surface layer of the particles that are considered neutral to fly through the plasma. Because the flying time of the raw material particles in self-generated plasma is expected to be short, the higher the probability/frequency with which the raw material particles come into contact with the plasma, the higher the frequency with which the raw material particles are sputtered, so that the number of active species to be generated increases and the deposition rate increases. It is favorable that the particles in flight creating the active species have a small size and a large specific surface area, and are dispersed.

After that, only the active species (atoms, molecules, and coalesced fine nanoparticles) of the sputtered raw material powder are densely deposited on the base material S on the stage 7 to form a highly insulating film.

Here, the raw material particles that contribute to deposition are raw material particles to be charged, raw material particles to induce plasma, and raw material particles to be sputtered in plasma. On the contrary, raw material particles that have passed through the plasma do not contribute to deposition. The ratio is approximately 99%. Therefore, in order to form a dense film, particles that do not contribute to deposition need to be inhibited from reaching the deposition surface (the base material S).

In this regard, the deposition device 1 according to this embodiment includes the mask member 20 that inhibits raw material particles specularly reflected on the irradiation surface 190 (see the arrow A2 in FIG. 2), of the raw material particles collided with the irradiation surface 190 of the target 19, from reaching the base material S on the stage 7. As shown in FIG. 1, the mask member 20 is a plate-shaped member that is disposed parallel to the support surface 71 of the stage 7, and is formed of a metal plate such as stainless steel in this embodiment. Alternatively, the mask member 20 may be formed of a metal plate or the like whose surface is covered with a resin such as polytetrafluoroethylene and polyimide.

The mask member 20 is disposed at a position that does not face the base material S on the stage 7 so as not to block the path toward the base material S of the fine particles passing in the direction indicated by the arrow A1 (see FIG. 2) from the irradiation surface 190 of the target 19. As a result, since it is possible to inhibit raw material particles that do not contribute to deposition and specularly reflected on the irradiation surface 190 of the target 19 from being mixed into the film, it is possible to stably form an alumina film having a desired film quality (insulating properties in this embodiment). In the case where the base material S is large and the deposition area is large, the mask member 20 includes a part facing the base material S, but it is essential not to block the path toward the base material S of the fine particles.

Hereinafter, an experimental example by the present inventors will be described.

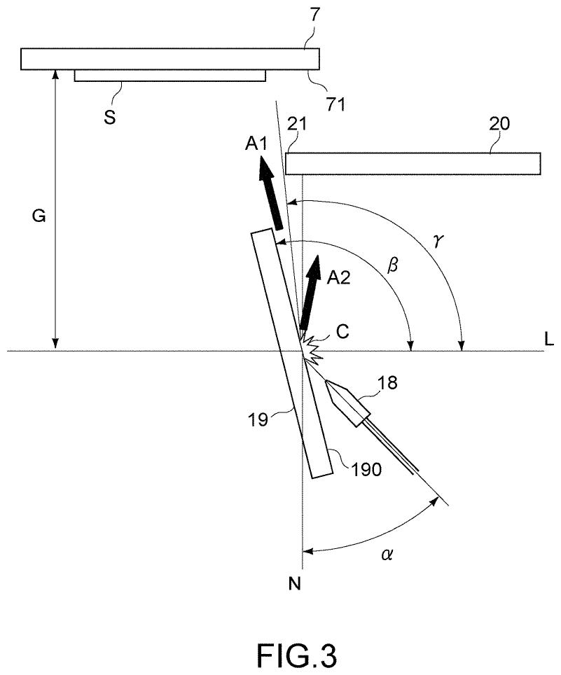

FIG. 3 is a side view showing the positional relationship between the nozzle 18, the target 19, the mask member 20, and the stage 7 in this experimental example.

As shown in FIG. 3, an angle α (hereinafter, referred to also as a nozzle angle α) formed by a normal direction of the stage 7 (direction perpendicular to the support surface 71) N and the injecting direction of the raw material particles (aerosol) from the nozzle 18 was set to 60°. Further, the tilt angle β (hereinafter, referred to also as a target angle β) between the irradiation surface 190 of the target 19 and a horizontal line L parallel to the support surface 71 of the stage 7 was set to 105° or 120°. Further, a distance G between a collision point C of the irradiation surface 190 of the target 19 and the raw material particles injected from the nozzle 18 and the support surface 71 of the stage 7 was set to 45 mm. As the target 19, a stainless-steel plate having a width of 30 mm, a length of 80 mm, and a thickness of 2 mm was used, and the target 19 was disposed so that the length direction was the perpendicular direction in the page of FIG. 3.

Further, as shown in FIG. 3, the mask member 20 formed of stainless-steel was disposed between the target 19 and one side of the stage 7 on the side of the target 19, parallel to the support surface 71 of the stage 7. An angle γ (hereinafter, referred to also as an edge angle γ) from the horizontal line L centered on the collision point C of the raw material particles on the irradiation surface 190 of the target 19 to an end portion 21 of the mask member 20 on the side of the stage 7 was set to 99°, 90°, or 81°.

Then, 80 g/l batch of powder obtained by mixing alumina fine particles having an average particle diameter of 0.4 μm and alumina fine particles having an average particle diameter of 3 μm at a weight ratio of 3 to 1 was used as the raw material particles P to form an alumina film of 40 mm×30 mm on the base material S. The pressure of the generation chamber 2 was set to approximately 50 kPa and the pressure of the deposition chamber 3 was set to approximately 900 Pa. Nitrogen or helium was used as the carrier gas for winding in the generation chamber 2, and the flow rate was 60 L/min (converted value) in the case of helium and 20 L/min in the case of nitrogen. The opening shape of the nozzle 18 was a slit shape having a width of 0.3 mm and a length of 30 mm. The base material S was a 50 mm-square aluminum plate whose surfaces were buffed.

### (Effects of Placing Mask Member)

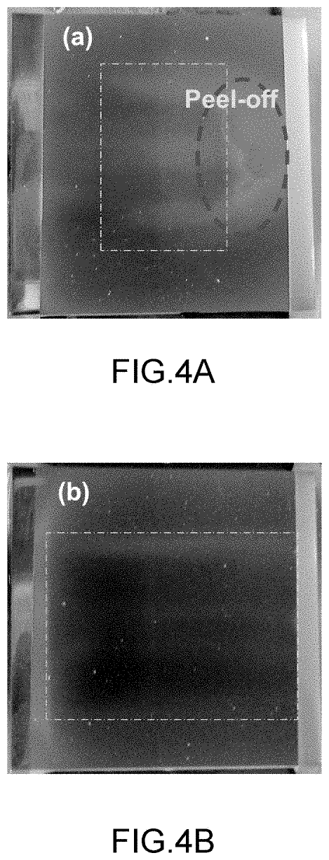

Surfaces of the alumina films deposited under the condition that the target angle β was 120° and the mask member 20 was absent/present were observed. FIG. 4A is a surface photograph of an alumina film deposited without the mask member 20, and FIG. 4B is a surface photograph of an alumina film deposited with the mask member 20 (edge angle γ is 99°). The deposited film exhibits black.

Under the condition that the mask member 20 was absent, film release (Peel-off) was observed in the vicinity of the initiation of deposition (an elliptical region indicated by a broken line on the right side in the figure) in the deposition with a scanning length of 20 mm (deposition duration of 8 minutes). It is considered that the raw material powder in the A2 direction (see FIG. 3) that are ejected from the nozzle 18 and specularly reflected on the irradiation surface 190 of the target 19 contribute thereto.

Meanwhile, under the condition that he mask member 20 was present, film release did not occur even in the deposition with a scanning length of 40 mm (deposition duration of 16 minutes), and it was confirmed that the placement of the mask member 20 for inhibiting the raw material powder specularly reflected on the irradiation surface 190 of the target 19 from mixing into the base material S was effective. Note that when the deposited alumina film was analyzed by EDS (Energy Dispersive X-ray Spectroscopy), the constituent elements of stainless steel, which is a constituent material of the target 19, were not detected, and thus it was judged that there was no contamination from the target 19.

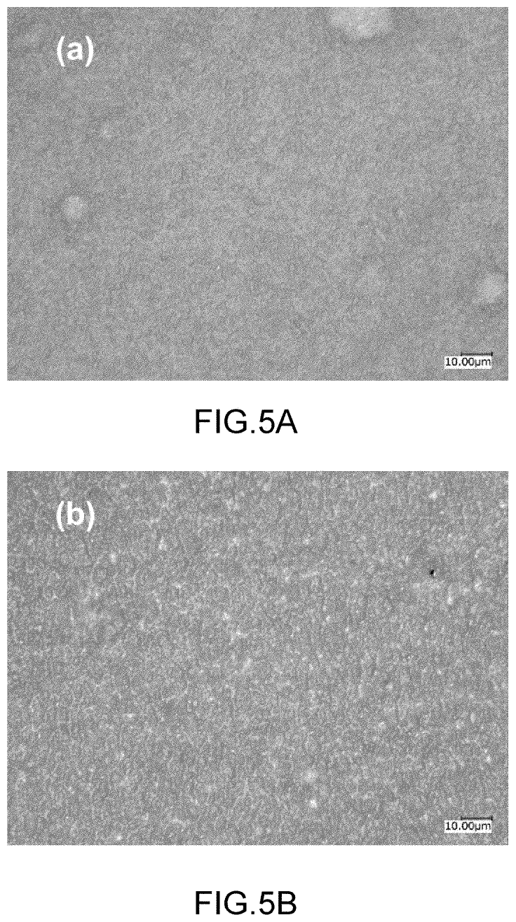

FIG. 5A is a stereomicroscopic image of the alumina film deposited without the mask member 20, and FIG. 5B is a stereomicroscopic image of the alumina film deposited with the mask member 20 (edge angle γ is 81°). Here, nitrogen was used as a carrier gas. For the film thickness measurement, a micrometer and a stereomicroscope were used.

The unevenness of the surface of the alumina film (film thickness: 13 μm) deposited without the mask member 20 was 0.2 μm or less, but many aggregated particles having a size of 10 μm to 20 μm were observed to be adhered on a part of the surface of the alumina film (see FIG. 5A).

Meanwhile, since the alumina film (film thickness: 19 μm) deposited with the mask member 20 had no large deposits, it was confirmed that the placement of the mask member 20 was effective for forming the dense film.

### (Effects of Edge Angle of Mask Member)

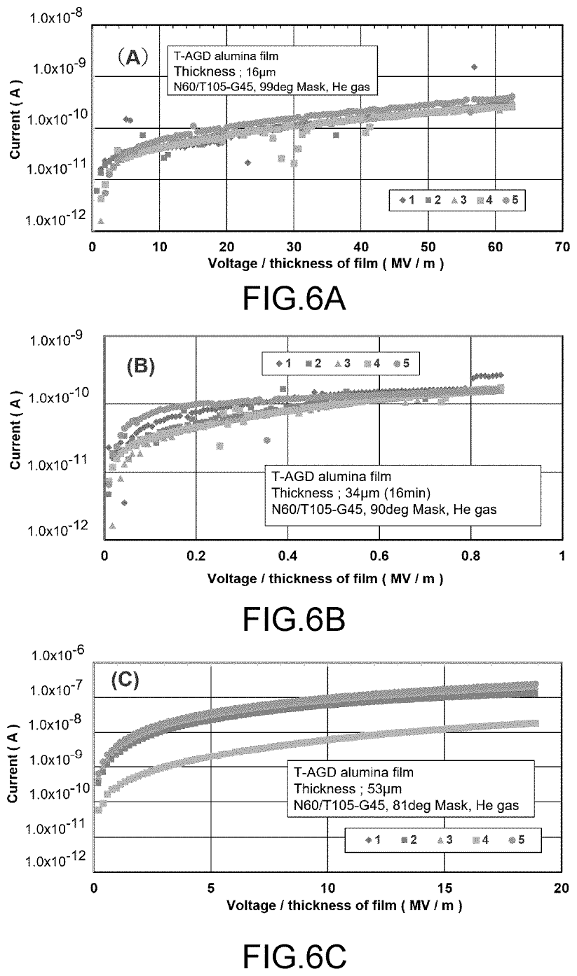

Next, the target angle β was fixed to 105°, and the edge angle γ of the mask member 20 was changed to prepare an alumina film. Using helium gas as a carrier gas, the I-V characteristics normalized by the film thicknesses of the prepared alumina films are shown in FIGS. 6A, 6B, and 6C.

A digital ultra-high resistance/micro-current meter “5450” manufactured by ADC was used for evaluating the I-V characteristics. The upper electrode was formed by sputtering an aluminum film having a thickness of 200 nm on an alumina film using a punching metal having a hole of 2 mm in diameter as a mask. A voltage was applied sequentially between the electrode and the base material S of the five points of the cross position (1 represent the film center, 2 and 3 respectively represent positions located 6 mm deep and 6 mm in front from the film center with respect to the injecting direction from the nozzle 18, and 4 and 5 respectively represent positions located 5 mm to the right and 5 mm to the left from the film center with respect to the injecting direction of the nozzle) for the respective alumina films to 1 kV in 10 V increments, and the leakage current value was measured.

FIG. 6A shows the I-V characteristic of the alumina film deposited by setting the edge angle γ of the mask member 20 to 99°. The film thickness was 16 μm. The leakage current when a DC of 1 kV was applied was 3.2×10⁻¹⁰ A, and it exhibited high insulating performance even in the thin film thickness.

FIG. 6B shows the I-V characteristic of the alumina film deposited by setting the edge angle γ of the mask member 20 to 90°. The film thickness was 34 μm. The leakage current when a DC of 1 kV was applied was 1.8×10⁻¹⁰ A, and it exhibited the high insulating performance.

FIG. 6C shows the I-V characteristic of the alumina film deposited by setting the edge angle γ of the mask member 20 to 81°. The film thickness was 53 μm. The leakage current when a DC of 1 kV was applied was 1.5×10⁻⁷ A, and insulation degradation was observed in spite of the thick film.

From these, it was confirmed that the insulating properties of the alumina film to be deposited is greatly affected by the edge-angle γ of the mask member 20.

### (Influence of Type of Gas Used)

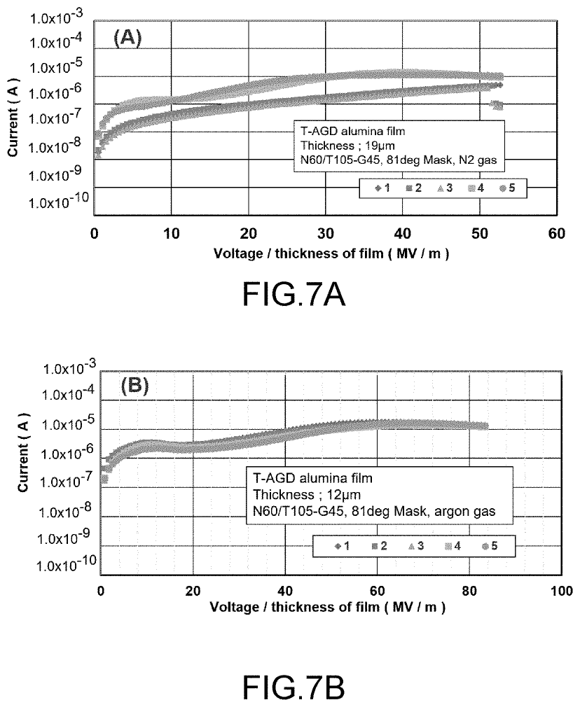

In order to examine the influence of the type of gas used as the carrier gas, an alumina film was prepared by using nitrogen gas or argon gas instead of helium gas under the condition that the target angle β was 105 degrees and the edge angle γ of the mask member 20 was 81 degrees, a thick film being obtained using helium gas under the same condition. FIG. 7A shows the I-V characteristic of the alumina film deposited using nitrogen, and FIG. 7B shows the I-V characteristic of the alumina film deposited using argon. These I-V characteristics were normalized by the thicknesses of the respective alumina films.

As shown in FIG. 7A, in the alumina film obtained using nitrogen gas, the deposition rate was approximately ⅓ of that in the alumina film obtained by using helium gas, and the film thickness was 19 μm. The I-V characteristic showed a leakage current value of 1.0×10⁻⁶ A when a DC of 1 kV was applied, and reduction in the insulation performance although no dielectric breakdown occurred.

Meanwhile, as shown in FIG. 7B, in the alumina film obtained using argon gas, the deposition rate was further reduced, and the film thickness was 12 μm. The I-V characteristic showed a leakage current value of 1.0×10⁻⁵ A when a DC of 1 kV was applied, although no dielectric breakdown occurred.

From the experimental results described above, improvement of the insulating performance and stabilization of the insulating properties of the deposited alumina film were achieved by the placement of the mask member 20. At the edge angle γ of the mask member 20 of 81° where the degree of opening was widened, an increase in the leakage current value of three orders of magnitude as compared with that at the edge angle γ of the mask member 20 of 90° was observed. It was presumed that there was an optimum position of inserting the mask member 20 for forming a film in which the alumina particles were tightly bonded. It was shown that alumina films prepared by the deposition device 1 including the mask member 20 had stable characteristics that exceed the breakdown field strength of bulk bodies.

### (Configuration Example of Mask Member)

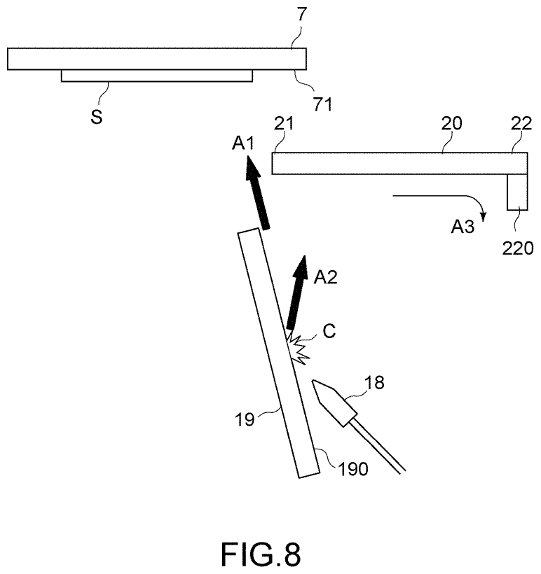

As described above, the mask member 20 is formed of a metal plate material, but is not limited thereto. For example, the mask member 20 shown in FIG. 8 may include a bent portion 220 folded back toward the side of the nozzle 18 at an end 22 opposite to one end 21 on the side of the stage 7. In this case, the bent portion 220 functions as a folded portion that guides raw material particles specularly reflected in the arrow A2 direction on the irradiation surface 190 of the target 19 to a predetermined direction. In the illustrated example, a flight path (see an arrow A3) through which the raw material particles specularly reflected on the irradiation surface 190 travel from the mask member 20 to the side of the nozzle 18 is formed. This allows the particles that have reached the mask member 20 to be guided to the side opposite to the stage 7. The folding angle of the bent portion 220 is typically 90°, but is not limited thereto. The bent portion 220 may be formed at any angle.

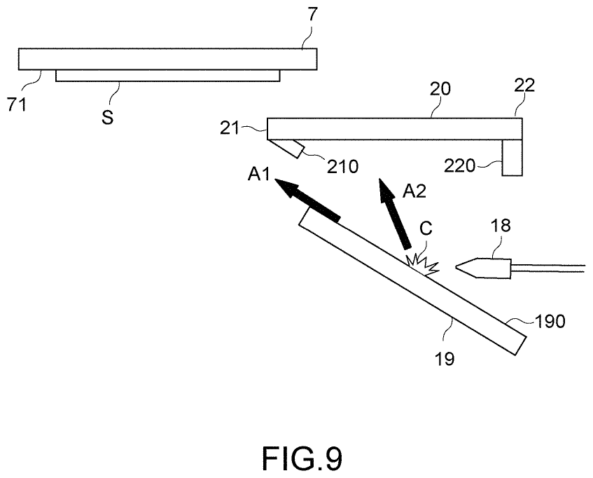

Further, as shown in FIG. 9, the mask member 20 may further include a bent portion 210 folded back toward the side of the target 19 at the one end 21 on the side of the stage 7 in addition to or instead of the bent portion 220. In this case, it is favorable that the bent portion 210 is folded back at an angle (e.g., 120 degrees or more) that does not block the path of the fine powder of the raw material particles that fly from the irradiation surface 190 of the target 19 toward the base material S in the direction of the arrow A1. As a result, since the relatively large raw material powder of the particle size reaching the mask member 20 can be inhibited from traveling toward the base material S, it is possible to effectively inhibit the raw material powder from mixing into the film on the base material S.

It should be understood by those skilled in the art that various modifications, combinations, sub-combinations and alterations may occur depending on design requirements and other factors insofar as they are within the scope of the appended claims or the equivalents thereof.

What is claimed is:

1. A deposition device, comprising:
a generation chamber configured to be capable of generating aerosol of raw material particles;
a deposition chamber configured to be maintained at a pressure lower than that of the generation chamber;
a transfer tubing that connects between the generation chamber and the deposition chamber, and includes, at a distal end thereof, a nozzle that injects the aerosol;
a target that is disposed in the deposition chamber, has an irradiation surface to be irradiated with the aerosol injected from the nozzle, and causes the raw material particles to be charged to plasma by collision with the irradiation surface;
a stage that has a support surface that supports a base material, fine particles of the raw material particles produced by discharging of the charged raw material particles being deposited on the base material; and
a mask member that is disposed in the deposition chamber, and inhibits raw material particles specularly reflected on the irradiation surface, of the raw material particles that have been collided with the irradiation surface, from reaching the stage.

2. The deposition device according to claim 1, wherein
the stage is disposed at a position that the raw material particles specularly reflected on the irradiation surface do not reach, on an axis that passes through the irradiation surface and is parallel to the irradiation surface.

3. The deposition device according to claim 1, wherein
the mask member is a plate-shaped member parallel to the support surface.

4. The deposition device according to claim 3, wherein
the mask member includes a folded portion that guides the raw material particles specularly reflected on the irradiation surface to a predetermined direction.

5. The deposition device according to claim 2, wherein
the mask member is a plate-shaped member parallel to the support surface.

6. The deposition device according to claim 5, wherein
the mask member includes a folded portion that guides the raw material particles specularly reflected on the irradiation surface to a predetermined direction.
